(19) United States
(12) Patent Application Publication
(10) Pub. No.: US 2016/0336187 A1
(43) Pub. Date: Nov. 17, 2016

(54) METHOD OF FORMING SEMICONDUCTOR STRUCTURE

(71) Applicant: UNITED MICROELECTRONICS CORP., Hsin-Chu City (TW)

(72) Inventors: En-Chiuan Liou, Tainan City (TW); Yu-Cheng Tung, Kaohsiung City (TW)

(21) Appl. No.: 14/737,507

(22) Filed: Jun. 12, 2015

(30) Foreign Application Priority Data
May 15, 2015 (CN) 201510247297.6

(51) Int. Cl. H01L 21/308; H01L 29/66; H01L 21/8234; H01L 21/311

(52) U.S. Cl. CPC H01L 21/3086; H01L 21/31144; H01L 29/6656; H01L 21/823431; H01L 21/3088

(57) ABSTRACT

A method of forming a semiconductor structure includes following steps. First of all, a plurality of mandrels is formed on a target layer. Next, a plurality of first liner is formed adjacent to two sides of the mandrels. Then, a plurality of second liners is formed adjacent to two sides of the first liners. After these, a plurality of third liners is formed adjacent to two sides of the second liners. Finally, the mandrels and the second liners are simultaneously removed.

### BACKGROUND OF THE INVENTION

1. Field of the Invention

The invention relates to a method of forming a semiconductor structure, and more particularly, to a method using spacer self-aligned quartic-patterning (SAQP) technique transferring patterns to form fin shaped structures.

2. Description of the Prior Art

With increasing miniaturization of semiconductor devices, it is crucial to maintain the efficiency of miniaturized semiconductor devices in the industry. However, as the size of the field effect transistors (FETs) is continuously shrunk, the development of the planar FETs faces more limitations in the fabricating process thereof, so that, non-planar FETs, such as the fin field effect transistor (finFET) having a three-dimensional structure have replaced the planar FETs and become the mainstream of the development. Since the three-dimensional structure of a finFET increases the overlapping area between the gate and the fin shaped structure of the silicon substrate, the channel region can therefore be more effectively controlled. This way, the drain-induced barrier lowering (DIBL) effect and the short channel effect are reduced.

The current formation of the finFET includes forming a fin shaped structure on a substrate primary, and then forming a gate on the fin shaped structure. The fin shaped structure generally includes the stripe-shaped fin formed by etching the substrate. However, with the demands of miniaturization of semiconductor devices, the width of each fin-shaped structure narrows and the spacing between the fin shaped structures shrinks. Thus, forming fin shaped structures which can achieve the required demands under the restrictions of miniaturization, physical limitations and various processing parameters becomes an extreme challenge.

### SUMMARY OF THE INVENTION

It is one of the primary objectives of the present invention to provide a method of forming a semiconductor structure, which forms a layout having a plurality of liners and then removes a portion of the liners, to form the fin shaped structures through transferring the aforementioned layout into a target layer underneath. Thus, an accurate layout of fin shaped structures may be sufficiently achieved, thereby providing uniform fin shaped structures having the same widths in relatively denser layout compared to the prior art.

To achieve the purpose described above, the present invention provides a method of forming a semiconductor structure including following steps. First of all, a plurality of mandrels is formed on a target layer. Next, a plurality of first liner is formed adjacent to two sides of the mandrels. Then, a plurality of second liners is formed adjacent to two sides of the first liners. After these, a plurality of third liners is formed adjacent to two sides of the second liners. Finally, the mandrels and the second liners are simultaneously removed.

According to the above, the method of forming fin shaped structures of present invention is accomplished by forming liners in rectangular shape, removing a portion of the liners and the mandrels due to the etching selectivity therebetween, and using the rest of liners as a mask to form the fin shaped structures. By using the aforementioned approach it may be desirable to form fin shaped structures with a finer size or a finer pitch, for forming more precise layout of the fin shaped structures

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic diagrams illustrating a method of forming a semiconductor structure according to a first embodiment of the present invention.

FIG. 5 to FIG. 8 are schematic diagrams illustrating a method of forming a semiconductor structure according to a second embodiment of the present invention.

FIG. 9 to FIG. 10 are schematic diagrams illustrating a method of forming a semiconductor structure according to a third embodiment of the present invention.

FIG. 11 to FIG. 13 are schematic diagrams illustrating a method of forming a semiconductor structure according to other embodiments of the present invention.

### DETAILED DESCRIPTION

To provide a better understanding of the present invention, preferred embodiments will be described in detail. The preferred embodiments of the present invention are illustrated in the accompanying drawings with numbered elements.

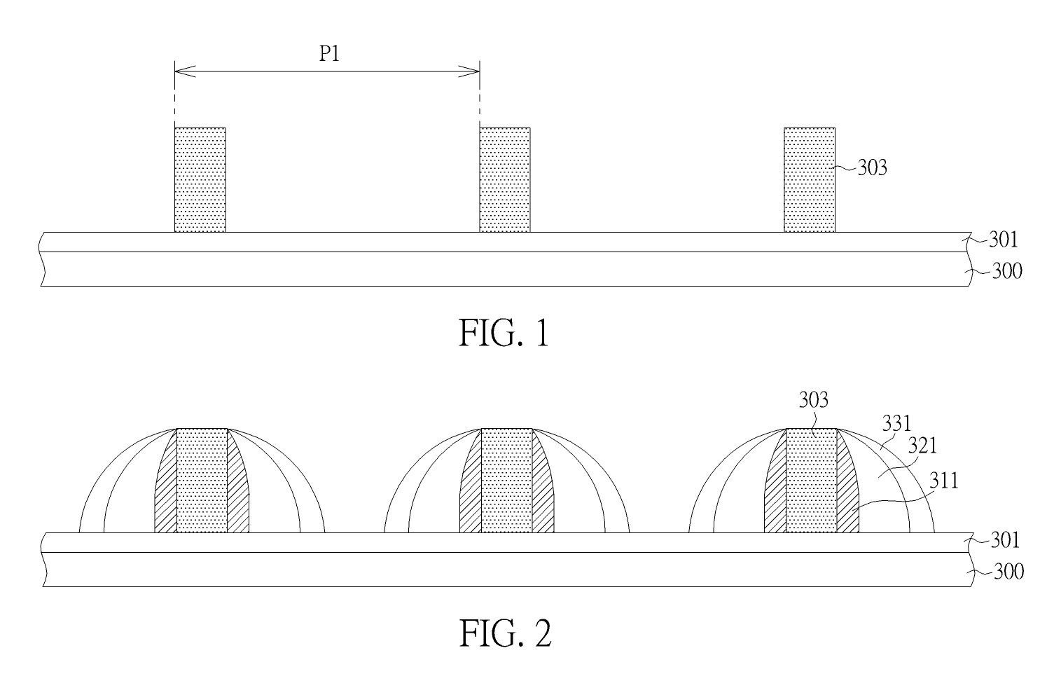

Please refer to FIG. 1 to FIG. 4, which are schematic diagrams illustrating a method of forming a semiconductor structure according to the first embodiment of the present invention. First of all, a target layer is provided, which may include a semiconductor layer 300 shown in FIG. 1, such as a silicon layer, an epitaxial silicon layer, a silicon carbide layer or silicon on insulation (SOI) layer, but is not limited thereto. In another embodiment, the target layer may include a conductive layer, such as an aluminum (Al) layer, a copper (Cu) layer or a tungsten (W) layer; or a non-conductive layer, such as a dielectric layer, but is not limited thereto.

Next, as shown in FIG. 1, a plurality of mandrels 303 is formed on the semiconductor layer 300 (namely, the target layer). In the present embodiment, the formation of the mandrels 303 may be integrated with the general semiconductor fabrication process. For example, a gate process may be performed to form a plurality of gate patterns which serve as the mandrels 303 on the substrate 300. Accordingly, the mandrels 303 may include polysilicon or other suitable materials having etching selectivity relative to the semiconductor layer 300 underneath, such as silicon oxide, silicon nitride. However, people in the art shall easily realize the mandrels 303 of the present invention are not limited to being formed through the aforementioned processes, and may also be formed through other forming methods.

Precisely speaking, each of the mandrels 303 is preferably isolated from each other, and any two adjacent mandrels 303 are spaced from each other in a pitch P1. The pitch P1 is at least greater than a width of the mandrels 303, but is not limited thereto. Also, in one embodiment, a mask layer 301 having a monolayer structure or multilayer structure may be optionally formed on the semiconductor layer 300, as shown in FIG. 1, before the mandrels are formed. The mask layer 301 may include silicon oxide, silicon nitride or silicon oxynitride, but is not limited thereto. In another embodiment, an etching process may be carried out according to the practical requirement, to remove a portion of each of the mandrels 303, thereby forming the mandrels (not shown in the drawings) having a relatively smaller width, but is not limited thereto.

Then, as shown in FIG. 2, a plurality of first spacers 311, a plurality of second spacers 321 and a plurality of third spacers 331 are formed sequentially on the semiconductor layer 300 to surround each of the mandrels 303. The formation of those spacers 311, 321, 331 may include firstly forming a first spacer material layer (not shown in the drawings) on the semiconductor layer 300, to cover each of the mandrels 303, and performing an etching back process to remove a portion of the first spacer material layer, and to expose a portion of the mask layer 301 or a portion of the semiconductor layer 300 (while the mask layer 301 is omitted), thereby forming the first spacers 311 adjacent to two sides of each of the mandrels 303. In the following, the aforementioned steps may be repeatedly carried out, to sequentially form the second spacers 321 and the third spacers 331 surrounding the first spacers 311.

It is worth noting that, since the first spacer material layer, the second spacer material layer and the third spacer material layer are all etched by using an isotropic etching process, while etching the three spacer material layers, only a sharp corner of the vertical portion of each of the three spacer material layers may be slightly removed, so as to form the first spacers 311, the second spacers 312 and the third spacers 313 having an arch-shaped sidewall as shown in FIG. 2. Furthermore, the first spacers 311, the second spacers 321 and the third spacers 331 are preferably formed from a material having etching selectivity relative to that of the mandrels 303, and the first spacers 311, the second spacers 321 and the third spacers 331 preferably all have etching selectivity relative to each other. For example, the first spacers 311 and the third spacers 331 may include an oxide, such as silicon oxide, and the mandrels 303 and the second spacers 321 may include a nitride, such as silicon nitride. Thus, through such differences of the etching selectivity therebetween, the mandrels 303 and the second spacers 321, or the first spacers 311 and the third spacers 331, may be simultaneously removed in the subsequent process, but is not limited thereto.

Otherwise, in one embodiment, the first spacers 311, the second spacers 321, the third spacers 331 and the mandrels 301 may optionally include the same or different width. For example, the second spacers 321 may have a width similar to that of each of the mandrels 303; and the first spacers 311 and the third spacers 331 may have a relatively smaller width, as shown in FIG. 2. In this way, while simultaneously removing the mandrels 303 and the second spacers 321 in the subsequent process, each of the remaining first spacers 311 and the third spacers 331 may space from each other in the same pitch, as shown in FIG. 4 for example. However, the formation and features of those spacers 311, 321, 331 are not limited to the aforementioned processes, and may include other forming methods, for example, integrating with the aforementioned gate process or including other materials.

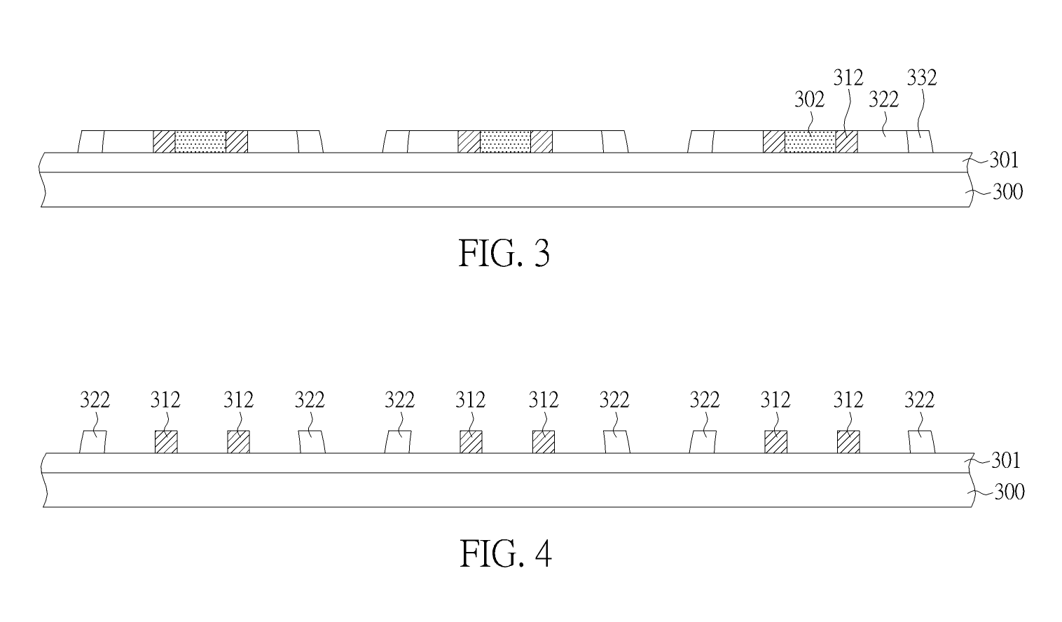

Following these, an appropriate planarization process, such as a chemical mechanical polish (CMP) process, an etching back process or a sequentially performed chemical mechanical polishing and the etching back process, may be selectively performed, to remove the arc-shaped top portions of the third spacers 331, the second spacers 321 and the first spacers 311, and the mandrels 303, so that, third liners 332, second liners 322, first liners 312 and mandrels 302 as shown in FIG. 3 may be formed. In one embodiment, the planarization process may be carried out through firstly forming a planarization layer (not shown in the drawings), to entirely cover the third spacers 331, the second spacers 321, the first spacers 311 and the mandrels 303, removing a portion of the third spacers 331, a portion of the second spacers 321, a portion of the first spacers 311 and a portion of the mandrels 303 by using the chemical mechanical polish process, and then completely removing the rest of the planarization layer. In other words, only the rectangular bottom portions of the third spacers 331, the second spacers 321, the first spacers 311 and the mandrels 303 remain, thereby being configured as the third liners 332, the second liners 322, the first liners 312 and the mandrels 302. Also, in the subsequent process, those liners 312, 322, 332 and the mandrels 302 maybe used as a mask to etch the semiconductor layer 300 underneath.

After that, as shown in FIG. 4, the second liners 322 and the mandrels 302 are simultaneously removed selectively due to the etching selectivity between those liners 312, 322, 332 and the mandrels 302. Namely, only the third liners 332 and the first liners 312 are used as a mask in the subsequent pattern transferring process, for forming a fin shaped structure (not shown in the drawings) in the semiconductor layer 300. For example, at least a dry etching, a wet etching process or a sequentially performed dry and wet etching process is carried out to directly transfer the patterns of the third liners 332 and the first liners 312 into the semiconductor layer 300 underneath, so that, the fin shaped structure having the same layout as that of the third liners 332 and the first liners 312 may be formed accordingly. Otherwise, in the embodiment of having the mask layer 301, the patterns of the third liners 332 and the first liners 312 may also be transferred into the mask layer 301 at first, the third liners 332 and the first liners 312 are removed, and the patterned mask layer 301 is then used as a mask to form the fin shaped structure. Furthermore, in another embodiment, a fin cut process may be performed to remove a part of the third liners 332, a part of the first liners 312, a part of the mask layer 301 or a part of the semiconductor layer 300, so as to form a desired layout of the fin shaped structure which is requested in the subsequent process, but is not limited thereto.

Through the above mentioned steps, the semiconductor structure according to the first embodiment of the present invention is obtained. In the present embodiment, plural spacers having an arc-shaped sidewall are formed to surround each mandrel at first, and the planarization process is performed remove a portion of the spacers, so as to form a plurality of liners in substantial rectangular shaped and mandrels which are adjacent to each other. After these, a portion of the liners and the mandrels may be selectively removed due to the etching selectivity therebetween, and the rest of the liners may be used as a mask in the subsequent process to form fin shaped structures directly. With such performance, a desired layout of uniform fin shaped structures having the same widths may be easily obtained, and also, the width or spacing between each fin shaped structures may reach 10 nm or less than 10 nm, for forming more precise layout of the fin shaped structures. In the present embodiment, the fin shaped structures are formed in the target layer including a semiconductor layer, so that, such fin shaped structures may be used to form a non-planar fin field effect transistor, but is not limited thereto. However, in another embodiment of providing a target layer including a conductive layer or dielectric layer, the fin shaped structures may also be used to form a wiring structure or a plug structure.

People in the art shall easily realize that the semiconductor structure of the present invention is not limited to being formed through the aforementioned processes, and may also be formed through other forming methods. Thus, the following description will detail the different embodiments of the semiconductor device and the forming method thereof of the present invention. To simplify the description, the following description will detail the dissimilarities among the different embodiments and the identical features will not be redundantly described. In order to compare the differences between the embodiments easily, the identical components in each of the following embodiments are marked with identical symbols.

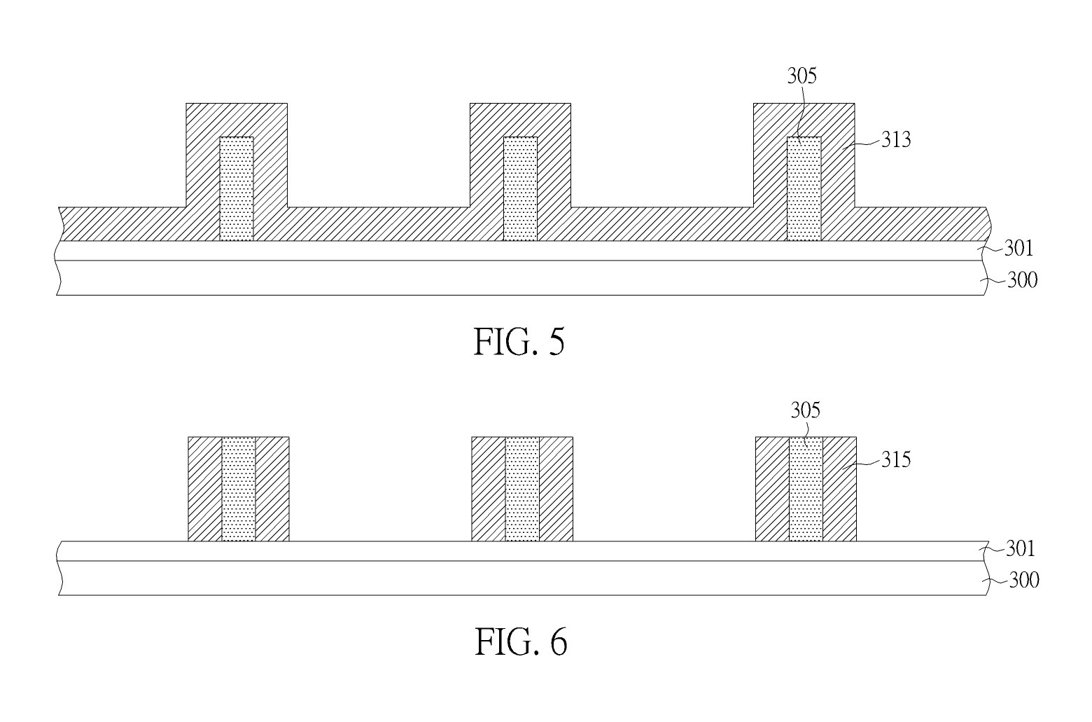

Please refer to FIG. 5 to FIG. 8, which is a schematic diagram illustrating a method of forming a semiconductor structure according to the second embodiment of the present invention. The formal steps in the present embodiment are similar to those in the first embodiment, and the differences between the present embodiment and the aforementioned first embodiment are that, the formation of the fin shaped structure in the present embodiment may be accomplished by directly forming a pattern layout including a plurality of rectangular liners, and transferring the pattern layout to form the fin shaped structure.

As shown in FIG. 5, an etching process may be optionally performed at first, to form mandrels 305 with a relatively smaller width. Next, a plurality of first liners 315 may be formed to surround each of the mandrels 305. Precisely speaking, the formation of the first liners 315 may include entirely forming a first material layer 313 on the semiconductor layer 300, to cover each of the mandrels 305, and performing a planarization process, such as a chemical mechanical polish process, an etching back process or a sequentially performed chemical mechanical polishing and the etching back process, to remove a portion of the first material layer 313 and to expose a portion of the mask layer 301 and a top surface of each of the mandrels 305, thereby forming the first liners 315 in rectangular shape, as shown in FIG. 6.

For example, in one embodiment, an etching back process may be optionally performed at first, to remove the first material layer 313 on the top surfaces of each mandrel 305 and on the mask layer 301. In this way, a vertical portion of the first material layer 313 which is adjacent to each of the mandrels 305 may be etched till the top portion thereof is slightly arced (not shown in the drawing). Then, a chemical mechanical polishing process is performed to remove the arced top portion of the first material layer 313, so that, the first liners 315 in regularly rectangular shape are formed accordingly. However, the method of forming the first liners 315 is not limited to the above mentioned steps but may include other methods, which are well known by one skilled in the arts, and are not described in detail hereafter.

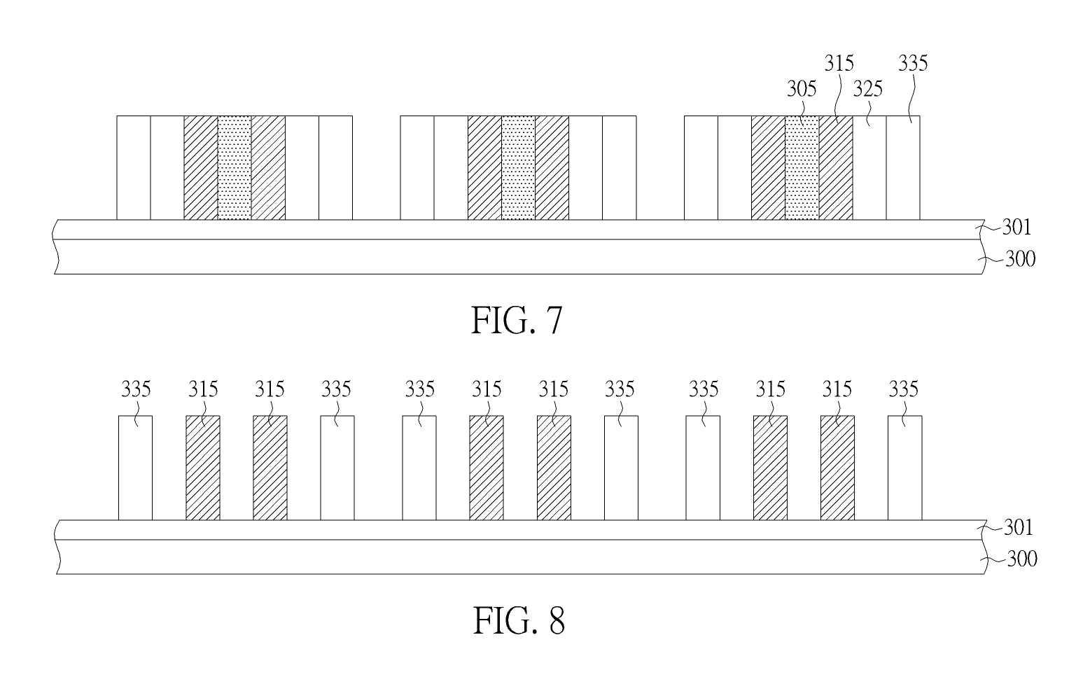

In the following, the aforementioned steps may be repeatedly carried out, to sequentially form a plurality of rectangular second liners 325 and a plurality of rectangular third liners 335 surrounding the first liners 315, as shown in FIG. 7. It is worth noting that, those liners 315, 325, 335 are preferably formed from a material having etching selectivity relative to that of the mandrels 305. For example, the first liners 315 and the third liners 335 may include an oxide, such as silicon oxide, and the second liners 325 and the mandrels 303 may include a nitride, such as silicon nitride, but is not limited thereto. In another embodiment, those liners 315, 325, 335 may also be formed through other forming process and include other materials.

Following these, as shown in FIG. 8, the second liners 325 and the mandrels 305 are simultaneously removed selectively due to the etching selectivity between those liners 315, 325, 335 and the mandrels 305. Namely, only the third liners 335 and the first liners 315 are used as a mask in the subsequent pattern transferring process, for forming a fin shaped structure (not shown in the drawings) in the semiconductor layer 300. For example, at least a dry etching, a wet etching process or a sequentially performed dry and wet etching process is carried out to directly transfer the patterns of the third liners 335 and the first liners 315 into the semiconductor layer 300 underneath, so that, the fin shaped structure having the same layout as that of the third liners 335 and the first liners 315 maybe formed accordingly. Otherwise, in the embodiment of having the mask layer 301, the patterns of the third liners 335 and the first liners 315 may also be transferred into the mask layer 301 at first, the third liners 335 and the first liners 315 are removed, and the patterned mask layer 301 is then used as a mask to form the fin shaped structure. Furthermore, in another embodiment, a fin cut process may be performed to remove a part of the third liners 335, a part of the first liners 315, a part of the mask layer 301 or a part of the semiconductor layer 300, so as to form a desired layout of the fin shaped structure which is requested in the subsequent process, but is not limited thereto.

Through the above mentioned steps, the semiconductor structure according to the second embodiment of the present invention is obtained. In the present embodiment, plural rectangular liners are formed directly, a portion of the rectangular liners is selectively removed due to the etching selectivity therebetween, and the rest of the rectangular liners may be used as a mask in the subsequent process to form fin shaped structures. With such performance, the etching mask with regular patterns may be sufficiently provided, so as to easily and conveniently form a desired layout of uniform fin shaped structures having the same widths, for forming more precise layout of the fin shaped structures.

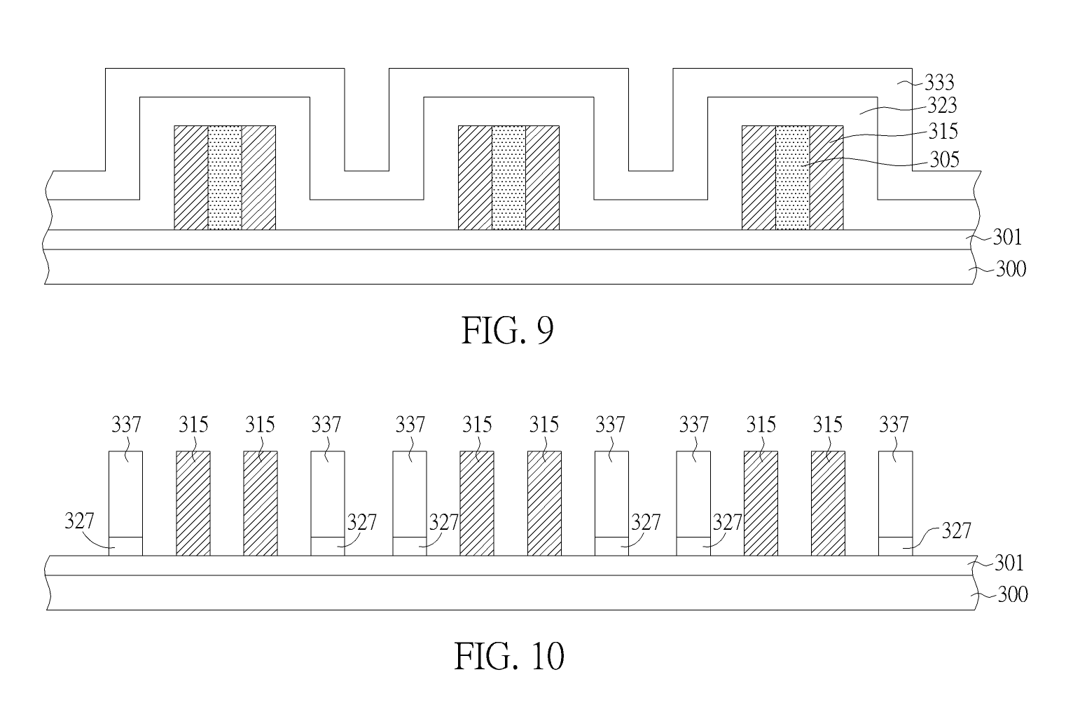

Please refer to FIG. 9 to FIG. 10, which is a schematic diagram illustrating a method of forming a semiconductor structure according to the third embodiment of the present invention. The formal steps in the present embodiment are similar to those in the second embodiment, and the differences between the present embodiment and the aforementioned second embodiment are that, the planarization process of the second material layer 323 and the third material layer 333 are carried out simultaneously. In other words, after forming the first liner 315 shown in FIG. 6, the second material layer 323 and the third material layer 333 are formed sequentially to cover the entire semiconductor layer 300. Then, the planarization process, such as a chemical mechanical polish process, an etching back process or a sequentially performed chemical mechanical polishing and the etching back process, is performed to simultaneously remove a portion of the second material layer 323 and a portion of the third material layer 333, so that, a portion of the mask layer 301 and the top surface of the mandrels 305 may be exposed, accordingly.

It is worth noting that, the second material layer 323 and the third material layer 333 are stacked on each other, such that, a vertical portion of the third material layer 333 may be directly formed on a portion of the second material layer 323, as shown in FIG. 9. In this case, the portion of the second material layer 323 may be protected by the third material layer 333 and shielded from etching during the planarization process, so that, a second liner in an “L” shape (not shown in the drawings) and the third liners 337 in a rectangular shape may be formed accordingly. Also, the third liners 337 may be formed on the horizontal portion of each of the L-shaped second liners, and which may not directly contact the semiconductor layer 300 or the mask layer 301 underneath.

After these, while selectively removing the second liners and the mandrels 305 in the subsequent process, the portion of the second liners may still be protected by the third liners 337 and shielded from the etching, so that, the portion of the second liners may not be removed, thereby forming a second liner 327 below the third liner 337, as shown in FIG. 10. Namely, the third liner 337 is formed on the second liner 327, and which may not directly contact the mask layer 301 or the semiconductor layer 300 underneath. In this way, the fin shaped structure (not shown in the drawings) of the present embodiment may be formed through transferring patterns of the first liner 315, the second liner 327, and the third liner 337 into the semiconductor layer 300. Except for the above mentioned difference, other steps of the present embodiment are all similar to those in the aforementioned second embodiment and will not be further detailed herein.

Additionally, although the aforementioned embodiments are all exemplified by forming mandrels 305, 303 with the same pitch or the same width, people in the art shall easily realize the present invention is not limited thereto. In other embodiments, mandrels with different pitches or different widths may also be formed optionally, or liners indifferent widths may also be formed optionally, according to the actual needs of the practical device, so as to form a more diverse fin shaped structure layout.

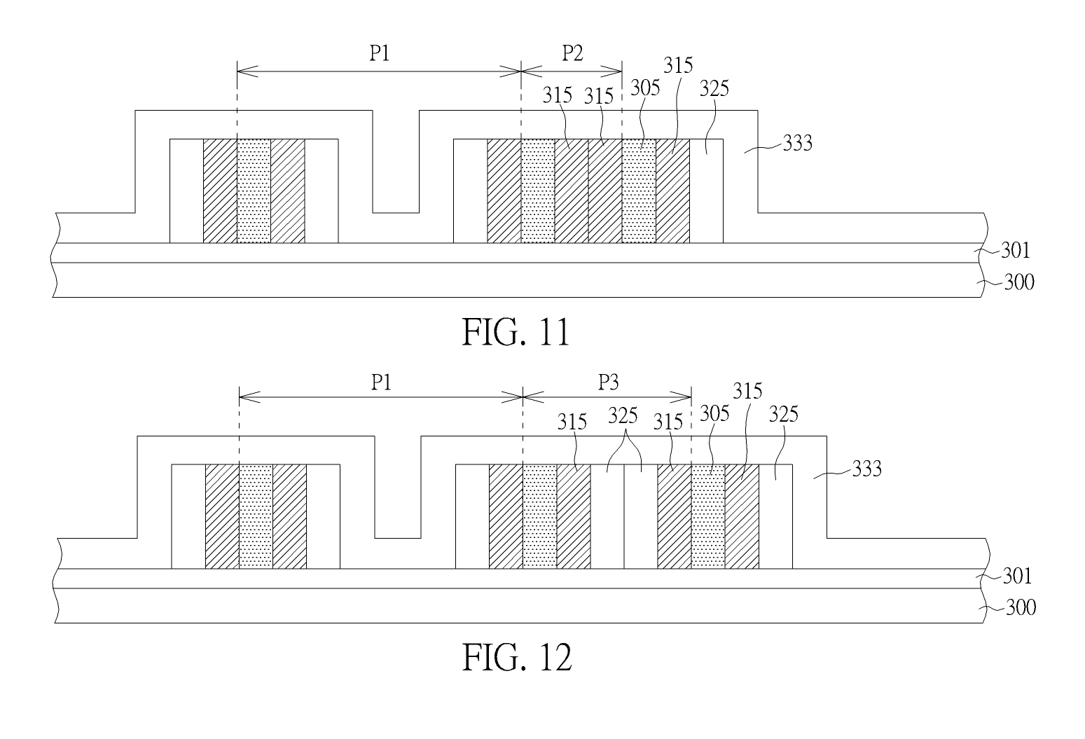

For example, please refer to FIG. 11 to FIG. 13, mandrels 306, 307, 308 with different pitches P1, P2, P3, P4 are formed respectively, wherein the pitches P2, P3, P4 are all less than the pitch P1, and the pitches P1, P2, P3, P4 are at least greater than a width of each of the mandrels 306, 307, 308, but is not limited thereto. Next, similar to the aforementioned processes, first liners 315, second liners 325, and third liners 335 surrounding the mandrels 306, 307, 308 are formed sequentially.

It is worth noting that, in one embodiment, the pitch P2 is less than the pitch P1, so that, a portion of the first liners 315 surrounded two adjacent mandrels 306 may merge with each other while forming the first liners 315, thereby forming the semiconductor device as shown in FIG. 11. In other words, since the pitch P2 between two adjacent mandrel 306 is relatively small, after forming the first liners 315 to surround the mandrels 306, no room may remain between two adjacent first liners 315. In this way, a first liner 315a having a relatively greater width may be formed, as shown in FIG. 11. Thus, after the second liners 325 and the mandrel 306 are removed, the first liners 315, 315a and the third liners 335 may be used as a mask in the subsequent process, for forming fin shaped structure in different sizes (not shown in the drawings).

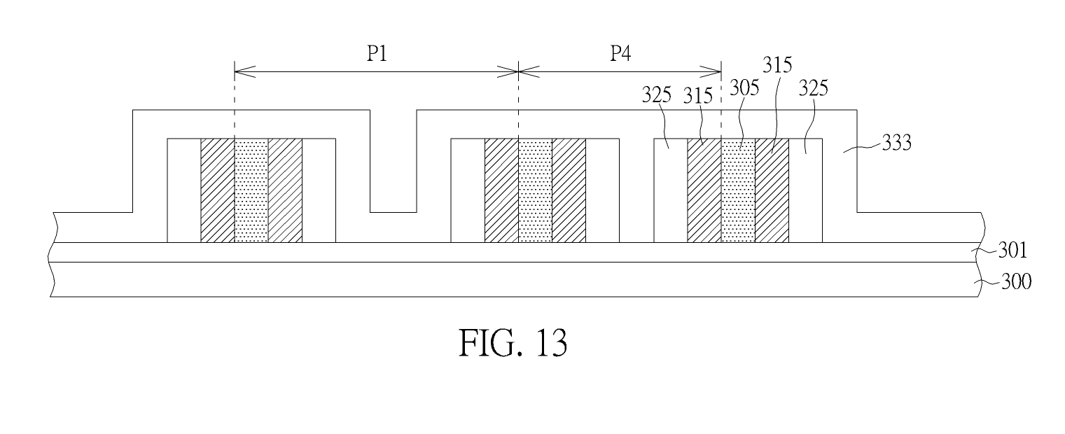

Otherwise, in another embodiment, mandrels 307, 308 having relatively less pitches P3, P4 may also be formed. In this way, a portion of the second liners 325 or a portion of the third liners 335 surrounded two adjacent mandrels 306 may merge with each other while forming the second liners 325 or the third liners 335, thereby forming the semiconductor device as shown in FIG. 12 or FIG. 13. Namely, since the pitch P3 or pitch P4 between two adjacent mandrel 307, 308 are relatively small, after forming the second liners 325 or the third liners 335 to surround the mandrels 307, 308, no room may remain between two adjacent second liners 325 or two adjacent third liners 335. In this way, a second liner 325a or a third liner 335a having a relatively greater width may be formed, as shown in FIG. 12 or FIG. 13. Thus, after the second liners 325, 325a and the mandrel 307, 308 are removed, the first liners 315 and the third liners 335, 335a may be used as a mask in the subsequent process, for forming fin shaped structure in different sizes or different pitches (not shown in the drawings).

Those skilled in the art will readily observe that numerous modifications and alterations of the device and method may be made while retaining the teachings of the invention. Accordingly, the above disclosure should be construed as limited only by the metes and bounds of the appended claims.

1. A method of forming a semiconductor structure, comprising:
forming a plurality of mandrels on a target layer;
forming a first material layer covering the mandrels;
performing an etching back process to remove the first material layer on top surfaces of the mandrels;
after the etching back process, performing a chemical mechanical polishing process to further remove a portion of the first material layer to form a plurality of first liners adjacent to two sides of the mandrels;
forming a plurality of second liners adjacent to two sides of the first liners;
forming a plurality of third liners adjacent to two sides of the second liners; and
simultaneously removing the mandrels and the second liners.

2. The method of forming a semiconductor structure according to claim 1, further comprising:
etching the mandrels to reduce a width of the mandrels before the first liners are formed.

3. The method of forming a semiconductor structure according to claim 1, wherein the mandrels have a same pitch.

4. The method of forming a semiconductor structure according to claim 1, wherein the mandrels have different pitches.

5. The method of forming a semiconductor structure according to claim 4, wherein at least two of the first liners adjacent to each other merge with each other.

6. The method of forming a semiconductor structure according to claim 4, wherein at least two of the second liners adjacent to each other merge with each other.

7. The method of forming a semiconductor structure according to claim 4, wherein at least two of the third liners adjacent to each other merge with each other.

8. The method of forming a semiconductor structure according to claim 1, wherein the mandrels, the first liners, the second liners and the third liners have different widths.

9-10. (canceled)

11. The method of forming a semiconductor structure according to claim 1, further comprising:
forming a second material layer covering the mandrels and the first liners;
removing a portion of second material layer to form the second liners.

12. The method of forming a semiconductor structure of claim 11, further comprising:
forming a third material layer covering the mandrels, the first liners and the second liners; and
removing a portion of third material layer to form the third liners.

13. The method of forming a semiconductor structure according to claim 1, further comprising:
forming a second material layer covering the mandrels and the first liners;
forming a third material layer covering the second material layer; and
removing a portion of second material layer and a portion of the third material layer simultaneously to form the second liners and the third liners.

14. The method of forming a semiconductor structure according to claim 13, wherein each of the third liners is formed on a portion of each of the second liners.

15. The method of forming a semiconductor structure according to claim 13, wherein each of the third liners does not directly contact the target layer.

16. The method of forming a semiconductor structure according to claim 14, wherein the portion of each of the second liners is not removed while the mandrels and the second liners are simultaneously removed.

17. The method of forming a semiconductor structure according to claim 16, further comprising:
etching the target layer by using the first liners, the portion of each of the second liners and the third liners as a mask.

18. The method of forming a semiconductor structure according to claim 1, further comprising:
etching the target layer by using the first liners and the third liners as a mask.

19. The method of forming a semiconductor structure according to claim 1, wherein the target layer comprises a semiconductor layer, a conductive layer or a non-conductive layer.
